(19) United States
(12) Patent Application Publication
(10) Pub. No.: US 2008/0030212 A1
(43) Pub. Date: Feb. 7, 2008

(54) ACTIVE PROBE CONTACT ARRAY MANAGEMENT

(75) Inventor: Roger Sinsheimer, Petaluma, CA (US)

Correspondence Address: BEYER WEAVER LLP, P.O. BOX 70250, OAKLAND, CA, 94612-0250, US

(73) Assignee: XANDEX, INC., Petaluma, CA (US)

(21) Appl. No.: 11/870,349

(22) Filed: Oct. 10, 2007

Related U.S. Application Data
(62) Division of application No. 11/435,024, filed on May 15, 2006.
(60) Provisional application No. 60/762,950, filed on Jan. 27, 2006.
(60) Provisional application No. 60/784,599, filed on Mar. 21, 2006.

(51) Int. Cl. G01R 1/073; G01R 31/02

(52) U.S. Cl. 324/758

(57) ABSTRACT

Methods and apparatus are described for controlling orientation of a probe contact array relative to a wafer contact array on a wafer. The probe contact array is configured on a probe card having first kinematic reference features associated therewith. The wafer is positioned in a wafer prober having an interface with second kinematic features. The first and second kinematic features are together operable to restrain relative motion between the probe card and the wafer prober when the probe card and the interface are docked. The orientation of the probe contact array relative to the wafer contact array is determined. Where the probe contact array is out of alignment with the wafer contact array, a height of at least one of the kinematic reference features is adjusted to bring the probe contact array and the wafer contact array into substantial alignment.

### RELATED APPLICATION DATA

The present application claims priority under 35 U.S.C. 120 and is a divisional application of U.S. patent application Ser. No. 11/435,024 filed May 15, 2006 (Attorney Docket No. XANDP008), which claims priority under 35 U.S.C. 119(e) to U.S. Provisional Patent Application No. 60/762,950 filed Jan. 27, 2006 (Attorney Docket No. XANDP008P), and U.S. Provisional Patent Application No. 60/784,599 filed Mar. 21, 2006 (Attorney Docket No. XANDP008P2), the entire disclosures of all which are incorporated herein by reference for all purposes.

### BACKGROUND OF THE INVENTION

The present invention relates to semiconductor test equipment and, more specifically, to techniques for monitoring and maintaining the orientation of probe contact arrays relative to the corresponding contacts on wafers.

In wafer sort, a wafer of semiconductor chips is tested in its raw form. Contact is made to the bond pads or solder bumps on the individual “die” on the wafer, electrically activating the die and allowing it to be tested for functionality. The hardware used to make this contact is called a “probe card.” Probe cards include a probe contact array of extremely hard and sharp contacts that match the array of bond pads or solder bumps on the wafer. This extremely closely spaced probe contact array is configured on a typically (but not always) round printed circuit board (PCB) which fans the probe contact array out to a much larger-spaced array of contacts that, in turn, is connected through various means to test electronics in a “test head.”

Semiconductor test equipment and testing methodology have advanced significantly over the years. Initially, only a single die was tested at a time, then two at once, then four, then 8, 16, 32, 64, and so on. In the very near future entire wafers with hundreds of dice on them will be tested at once, i.e., with a single “touch” of the probe contact array. To achieve reliable testing of so many dice, the entire probe contact array must be coplanar with the corresponding contacts on the top surface of the wafer to a very fine level of accuracy.

For wafer sort, the probe card is placed in a fixed, ideally rigid, relationship to the “wafer prober,” either mounted to a tester-prober interface, or mounted to the top plate of the wafer prober, i.e., the “head plate.” Through a fairly long and involved series of steps, the contacts (e.g., bond pads or solder bumps) on the wafer to be tested are brought into X-Y-theta alignment with the probe contact array by the wafer prober. In the ideal case in which all of the tips of the probe contact array are perfectly aligned to each other (i.e., coplanar) and all of the contacts on the wafer are of the same height, all of the tips of the probe contact array would touch the wafer contacts simultaneously.

In the real world this does not happen due to lack of perfect coplanarity of the probe contacts within the probe array and, on a more macro level, the lack of coplanarity between the probe contact array and the wafer. This lack of coplanarity (relating to either or both of pitch and roll errors) results in one side of the probe contact array touching the wafer contacts first. Ideally this second, macroscopic error would be reduced to zero.

As the wafer is raised towards the bottom of the probe card, some contact somewhere within the probe array will first make contact to the wafer. This is the “first touch”. The wafer continues to rise towards the probe card, and some other contact somewhere within the probe array will be the last one to make contact, this is the “last touch”. The terminology used in the industry to describe the allowable range for this initial motion (i.e., from first contact touch to last contact touch) is called “Z-budget”. Pitch and/or Roll errors will cause one side of the probe contact array to touch first, increasing Z-budget in proportion to the magnitude of the error(s).

A typical standard within the industry for Z-budget for large array probe cards dictates that when the first probe contact touches, the last contact should touch after 15 microns of additional upward travel of the wafer. After the last probe contact touches, the wafer is lifted an additional distance often referred to as “overdrive.” A typical overdrive distance is 75 microns, though this number can vary depending on a number of factors including the technology used to create the probe contacts.

If the difference between the first touch and the last touch exceeds the Z-budget due to a pitch and/or roll error in the positioning of the probe contact array relative to the top of the wafer, the combination of this excess and the overdrive on the first-touch probe contacts could result in damage to the probe contacts, or, if the contacts survive, so much force might be placed on the corresponding bond pads or solder bumps that they, or the underlying electronic hardware, might be damaged.

In view of the foregoing, there is a need for more reliable techniques for monitoring and controlling the orientation of probe contact arrays relative to the corresponding contacts on the device under test.

### SUMMARY OF THE INVENTION

The present invention provides techniques by which errors relating to the lack of coplanarity between a probe contact array and a wafer may be reduced or eliminated. According to specific embodiments of the invention, methods and apparatus are provided for controlling orientation of a probe contact array relative to a wafer contact array on a wafer. The probe contact array is configured on a probe card having first kinematic reference features associated therewith. The wafer is positioned in a wafer prober having an interface with second kinematic features. The first and second kinematic features are together operable to restrain relative motion between the probe card and the wafer prober when the probe card and the interface are docked. The orientation of the probe contact array relative to the wafer contact array is determined. Where the probe contact array is out of alignment with the wafer contact array, a height of at least one of the kinematic reference features is adjusted to bring a first plane associated with the probe contact array and a second plane associated with the wafer contact array into substantial alignment.

According to a specific embodiment, a probe card is provided for facilitating electrical contact with a wafer contact array on a wafer. The wafer is positioned in a wafer prober having an interface. The probe card includes a probe card structure and a probe contact array disposed on the probe card structure. First kinematic reference features are disposed on the probe card structure. The first kinematic features are operable together with second kinematic reference features associated with the interface to restrain relative motion between the probe card and the wafer prober when the probe card and the interface are docked. Each of the first kinematic reference features is operable to move relative to the probe card structure to facilitate alignment of the probe contact array with the wafer contact array.

According to another specific embodiment, a wafer prober is provided for facilitating testing of a wafer in conjunction with a probe card. The probe card has a probe contact array for contacting a wafer contact array on the wafer. The wafer prober includes an interface having first kinematic reference features disposed thereon. The first kinematic reference features are operable together with second kinematic reference features associated with the probe card to restrain relative motion between the probe card and the wafer prober when the probe card and the interface are docked. Each of the first kinematic reference features is operable to move relative to the interface to facilitate alignment of the probe contact array with the wafer contact array.

According to yet another specific embodiment, methods and apparatus are provided for controlling planarity of a probe contact array in contact with a wafer contact array on a wafer. The probe contact array is configured on a probe card having first kinematic reference features associated therewith. The wafer is positioned in a wafer prober which includes an interface having second kinematic features associated therewith. The first and second kinematic features are together operable to restrain relative motion between the probe card and the wafer prober when the probe card and the interface are docked. A plurality of forces associated with at least some of the first and second kinematic reference features is measured. A planarizing force is applied to a back side of the probe card opposite the probe contact array to oppose deformation of the probe card. The magnitude of the planarizing force is determined with reference to the plurality of forces.

A further understanding of the nature and advantages of the present invention may be realized by reference to the remaining portions of the specification and the drawings.

### BRIEF DESCRIPTION OF THE DRAWINGS

FIGS. 1A-1C are simplified diagrams of components of a semiconductor test system designed according to a specific embodiment of the invention.

FIGS. 2A-2C are simplified diagrams of components of a semiconductor test system designed according to another specific embodiment of the invention.

### DETAILED DESCRIPTION OF SPECIFIC EMBODIMENTS

Reference will now be made in detail to specific embodiments of the invention including the best modes contemplated by the inventor for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, specific details are set forth in order to provide a thorough understanding of the present invention. The present invention may be practiced without some or all of these specific details. In addition, well known features may not have been described in detail to avoid unnecessarily obscuring the invention.

In some direct-dock tester-prober interface designs, the probe card backside stiffener has three substantially planar surfaces which are kinematically referenced to a plane defined by three corresponding curved surfaces (e.g., portions of a sphere) which in turn reference an extremely rigid structure, which in turn is connected to the wafer prober. Kinematics in this context typically define the pitch-roll-z orientation of the probe contact array relative to the wafer contact array. Alternative means (e.g., fixed pins in the interface which correspond to holes and/or slots in the probe card) are typically used to define the x-y-theta orientation of the array. Unfortunately, conventional probers have no mechanism for compensating for pitch and roll errors, or for z errors within the probe contact array.

Various mechanisms exist for accomplishing kinematic referencing which may be employed with various embodiments of the invention. One approach in which kinematic surfaces are held in intimate contact with each other by a self-compensating spring-loaded clamping mechanism is described in detail in U.S. Pat. No. 6,833,696, the entire disclosure of which is incorporated herein by reference for all purposes. It will be understood that embodiments of the invention described below assume that some mechanism is being employed to facilitate and maintain contact between the kinematic reference features described. However, in order to avoid obscuring the important aspects of the invention, and in view of the fact that such mechanisms are within the understanding of one of skill in the art, the details of such mechanisms are not shown.

Given that damage to either the wafer or the probe card is unacceptable, and given that the wafer prober cannot typically compensate for pitch or roll errors in the position of the probe contact array, the present invention provides techniques by which kinematic reference features are employed to control the orientation of the probe contact array relative to the wafer surface. The present invention provides a reliable mechanism which is operable to change the position of the surfaces of the kinematic reference features relative to each other in the dimension normal to the nominal plane of the probe contact array and/or the wafer contact array (i.e., the position in z or the vertical or up/down dimension in many systems). A feedback mechanism ensures that the adjustment of these surfaces is correct.

According to various embodiments of the invention, a variety of mechanisms may be employed to reliably change the z-positions of the surfaces of the kinematic reference features. According to a first class of embodiments, piezoelectric mechanisms are employed to lift and lower these surfaces relative to the mounting locations of the corresponding kinematic reference features. Piezoelectricity is the ability of certain crystals to generate a voltage in response to applied mechanical stress. The piezoelectric effect is reversible in that piezoelectric crystals, when subjected to an externally applied voltage, can change shape by a small amount. This is also referred to as the “converse” piezoelectric effect. As will become clear, one or both of these effects may be employed with the various implementations of the present invention based on the piezoelectric effect.

According to another class of embodiments, mechanical mechanisms, e.g., motor driven screws or inclined planes, are introduced between the kinematic reference features and their mounting locations to create the motion required with predictable results and no backlash. Such mechanical mechanisms may be employed with piezoelectric sensors to monitor the orientation of the probe contact array. Alternatively, and as discussed below, other mechanisms for monitoring the orientation of the probe contact array may be employed with such embodiments.

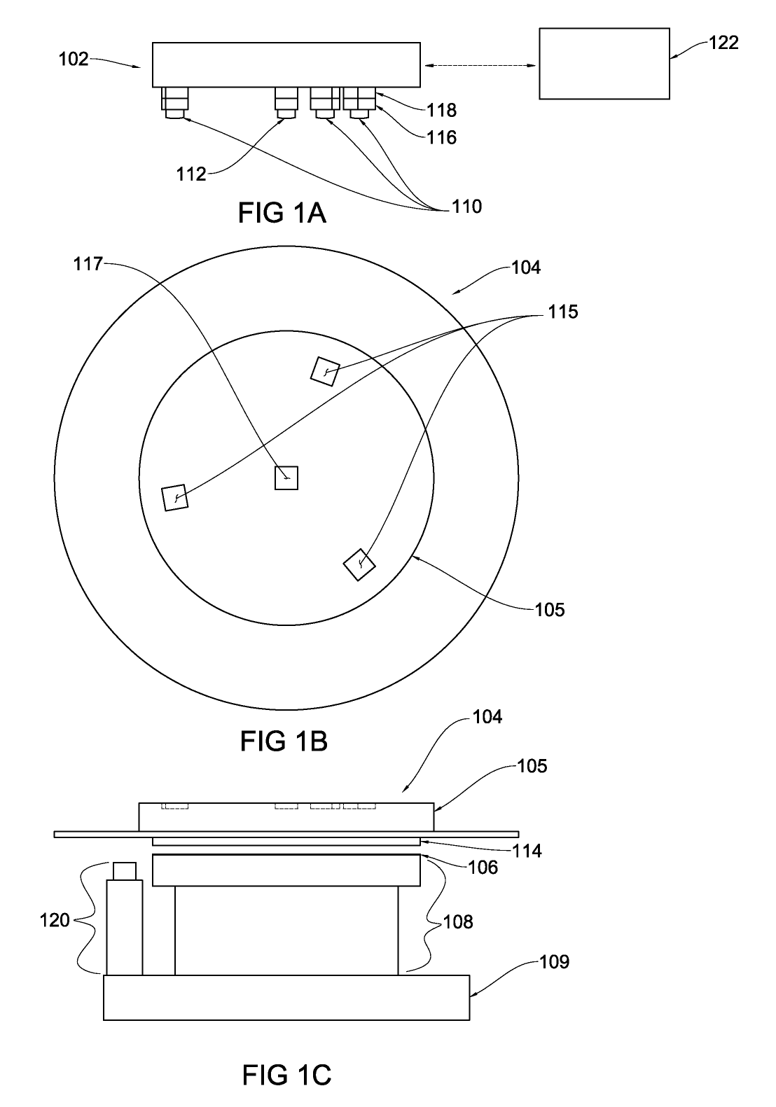

FIGS. 1A-1C are simplified diagrams of components of a semiconductor wafer test system designed according to a specific embodiment of the invention. FIG. 1A shows a side view of a simplified wafer probe test interface 102 designed in accordance with a specific embodiment of the present invention. As used herein, the term “wafer probe test interface” refers to the portion of a wafer test system which interfaces with a probe card using kinematic reference features. Wafer probe test interfaces are referred to within the semiconductor test industry using a variety of terms including, for example, wafer sort interface, top hat, frog ring, probe ring, interface ring, probe tower, interface tower, Pogo™ tower, or HiFix interface. It should be understood then, that the term as used herein may include any of these or equivalent structures.

FIG. 1B shows a backside plan view of a probe card 104. FIG. 1C shows a side view of probe card 104 positioned relative to a wafer 106 on a wafer chuck 108 (which moves in z and theta) which, in turn, is on a wafer chuck carriage 109 (which moves in x and y).

Wafer probe test interface 102 includes three kinematic reference features 110 (having curved surfaces which together define a plane) and an optional additional support 112 which may be similarly constructed. The function and purpose of such an additional support according to a more specific embodiment of the invention will be described below. According to various embodiments and as will be described, kinematic reference features 110 and/or additional support 112 may each comprise one or more piezoelectric components.

Probe card 104 includes a probe contact array 114 and three kinematic reference features 115 (e.g., substantially planar surfaces on probe card “backside” stiffener 105) which correspond to kinematic reference features 110 on interface 102. An optional and similar reference feature 117 may also be provided for embodiments in which additional support 112 is present. As mentioned above, intimate contact between the kinematic reference features of wafer probe test interface 102 and probe card 104 is maintained using any of a variety of mechanisms, the details of which are not shown in the figures in order to avoid unnecessarily obscuring important aspects of the depicted embodiments.

According to a specific embodiment, wafer 106 is initially raised up against array 114 with the assumption that the wafer and the array are properly oriented relative to each other, i.e., that they are substantially coplanar. As the wafer is being raised after “first touch,” the force on kinematic reference features 110 are measured using the piezoelectric effect.

Because probe contact array 114 is always centered on probe card 104, if the respective loads on the three kinematic reference features 110 are equal, probe contact array 114 is assumed to be coplanar with the contact array on the wafer. Given that a single probe contact typically creates more than 5 grams of force, and that today's large array probe cards have many tens of thousands of contacts, there is sufficient force available to detect any difference among the loads. It should be noted that the term “coplanar” in this context refers to the degree of parallelism between a first plane representing the nominal plane of the entire probe contact array and a second plane representing the nominal plane of the entire wafer contact array. It will be understood that the heights of the individual contacts in each array will typically vary with respect to each other to some degree as discussed above.

If, on the other hand, the loads are determined not to be equal, the converse piezoelectric effect is used to adjust the height of one or more of kinematic reference features 110 to bring the loads into substantial equilibrium. That is, according to such embodiments, the piezoelectric effect is used to monitor the orientation of the probe contact array (as represented by voltages generated by the loads on the kinematic reference features), and the converse piezoelectric effect to control the orientation of the probe contact array (by applying voltages to and causing deformation of one or more of the kinematic reference features in the z-direction). Both of these functions may be accomplished using a single “pusher” piezoelectric component for each kinematic reference feature 110 (e.g., just component 116). That is, according to such an embodiment, the height of each kinematic reference feature is adjusted by applying voltages to pusher components 116, while the orientation of the probe contact array is monitored with reference to the “back EMF” from these same components.

Alternatively, each kinematic reference feature 110 may include two piezoelectric components, e.g., sensor components 118 mounted in line with pusher components 116. According to such an approach, the monitoring of the orientation of the probe contact array may be done independently from the adjustment.

Suitable materials for implementing the piezoelectric components of the kinematic reference features include, for example, various forms of “PZT” material, i.e., lead (Pb), zirconium (Z) titanate (Ti). And this basic set of materials can be modified for specific enhanced properties with the addition of elemental dopants like nickel, magnesium, niobium, etc. Piezoelectric components suitable for use with various embodiments of the invention may be provided by, for example, EDO Corporation of Salt Lake City, Utah; Physik Intrumente of Irvine, Calif.; and Piezomechanik of Lake Forest, Calif. It will be understood that, notwithstanding these references to specific materials and component providers, a wide range of piezoelectric materials and components may be employed without departing from the invention.

In general, control of the various components described herein may be accomplished in a wide variety of ways using various combinations of data processing hardware and software. For example, existing control systems (e.g., wafer probe test interface control system 122) may be employed to monitor and control the kinematic reference features of the present invention, particular in embodiments in which these reference features are integrated with the wafer probe test interface as shown in FIG. 1A. As the implementation of such monitoring and control is well within the understanding of a one of skill in the art, further details are not provided here in order to avoid obscuring the more important features of the present invention.

According yet another class of embodiments, alternative mechanisms are employed for monitoring the orientation of the probe contact array. According to one such embodiment, an upward looking camera 120 mounted in the wafer prober is used to determine the relationship of the probe contact array to the wafer chuck (and thus the wafer contact array). Most modern wafer probers have such a camera mounted next to the wafer chuck that looks up at the probe contact array. This camera is conventionally used to determine where the probe contact array is in x, y, theta and z, for the purpose of directing the alignment of the probe contact array to the wafer contact array in these dimensions. Because this alignment system can determine where the probe contacts reside in z, this information may used to control the adjustment of the surfaces of the kinematic reference features and thereby bring the probe contact array into alignment relative to the wafer contact array, i.e., correct pitch and/or roll error.

It will be understood that, although a preexisting camera may be present, embodiments of the invention are contemplated in which an alternate auxiliary camera is used for implementing the invention. In addition, the adjustment of the kinematic reference features in response to the data retrieved with the camera may be done using piezoelectric “pushers” or some other mechanical mechanism (e.g., a screw or inclined plane) as mentioned above. Sensing of forces on kinematic reference features and any additional supports may be accomplished using a variety of mechanisms in addition to are as alternatives to piezoelectric components including, for example, strain gauges or any other suitable force or pressure sensitive technology.

As arrays become larger and larger, the span between the three kinematic supports and the probing force become so great that the physical space limitations behind the array do not allow for a sufficiently stiff support to prevent unacceptable deformation of the probe array. Therefore, according to a specific embodiment of the invention, at least one additional support 112 can be added directly behind the probe contact array 114. The purpose of this additional support is to provide a reaction force to oppose or prevent deformation of the probe array. As can be appreciated from the figure, the addition of this support greatly reduces the effective span between the kinematic supports 110 and, as will be discussed, commensurately reduces the deformation of the probe contact array. According to different embodiments, support 112 may be mounted either on the probe card or on the test head as long as there is a corresponding and sufficiently rigid component mounted on the opposing assembly against which support 112 can push.

According to a specific embodiment of the invention, the additional support is similar in function to the three kinematic reference features described above, including a “pusher” piezoelectric component and a “sensor” piezoelectric component in line with one another. However, it should be noted that, as with the kinematic reference features described above, the additional support may employ a variety of mechanisms including, for example, a single piezoelectric component, a mechanical mechanism, a mechanical mechanism with a force sensor, etc.

After ensuring that the probe contact array is coplanar with the wafer contact array using, for example, one of the techniques described above, the additional support is extended until a resistance is met, indicating that it is in contact with the back of the probe array stiffener (or a corresponding structure on the wafer probe test interface). Once probing begins, the probing force is observed on all the support points (e.g., including the kinematic reference features) using the sensor capability. By comparing these forces, and by using a lookup table to compensate for compression of the supports, planarity of the probe contact array can be maintained.

According to a more specific embodiment, the lookup table employed in the above-described technique is created by employing the following process: The first step is to compress one or more of the supports under load and observe its spring rate. Knowing the spring rate of the support (and any underlying supports as well), and the loads (from the sensors), the support points (i.e., the kinematic reference features and the additional support(s) behind the probe contact array) can be maintained coplanar to each other during system operation, thereby maintaining the planarity of the probe contact array during probing. It should be noted that while the forces on the three kinematic supports may be substantially equal to each other during probing, the force associated with the additional support (as determined by an offline engineering calculation) will likely be different and this difference will accordingly be reflected in the lookup table.

It should be noted that, according to some embodiments and in view of the fact that kinematic reference features and the additional supports designed in accordance with the invention may be assumed to have sufficiently similar responses within normal manufacturing tolerances, the lookup table may be built using measurements of only one of the structures and by performing an analytical study of the stiffness of the specific probe card assembly.

It should also be noted that additional support 112 may be employed independently from the techniques described herein for orienting the probe contact array with the wafer contact array. That is, such supports may be used to augment the stiffness of large probe contact arrays during wafer test as well as in a variety of other contexts including, for example, standard wafer sort.

While the invention has been particularly shown and described with reference to specific embodiments thereof, it will be understood by those skilled in the art that changes in the form and details of the disclosed embodiments may be made without departing from the spirit or scope of the invention. For example, embodiments of the invention have been described above which show adjustable kinematic reference features associated with the wafer probe test interface. However, it should be understood that embodiments are contemplated in which adjustable kinematic reference features are associated with the probe card instead.

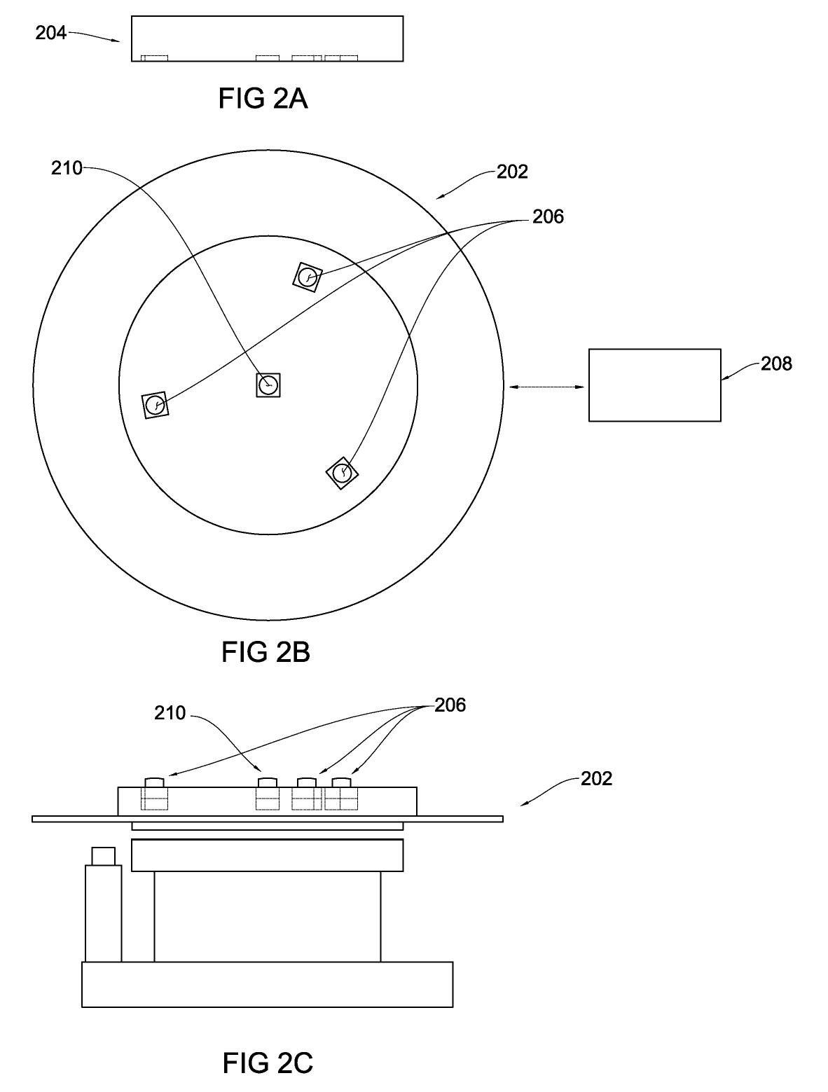

One such embodiment is illustrated in the diagrams of FIGS. 2A-2C. As can be seen, these diagrams are similar to those shown in FIGS. 1A-1C except that the roles of the kinematic reference features are reversed. That is, in this embodiment probe card 202 (instead of wafer probe test interface 204) includes adjustable kinematic reference features 206, the heights of which may be adjusted to align the probe contact array with the wafer contact array using any of the mechanisms described above. Optionally, an additional support 210 may be provided to help maintain the planarity of the probe contact array as described above with reference to additional support 112.

An approach such as that shown in FIGS. 2A-2C may be useful, for example, where replacement or retrofitting of the wafer probe test interface is undesirable. It should be understood by the reader that FIGS. 2A-2C are intended to provide a general understanding of the invention, and that an actual implementation may have to be adjusted in accordance with the specific test interface that is to be retrofitted.

And according to such embodiments, it may also be necessary or desirable to provide a separate control system 208 associated with probe card 202 to provide any of the monitoring and control functionalities for implementing the invention. Again, the details of the data processing hardware and software which may be used to implement such functionalities are well within the understanding of one of skill in the relevant arts and are therefore not provided here.

It should also be noted that, according to embodiments in which the adjustments of the kinematic reference features or additional stiffness support(s) are done using mechanical mechanisms (e.g., screws or inclined planes), such adjustments may be accomplished both automatically (e.g., under the control of a processor associated with some portion of the test system), or manually (e.g., by a technician with a screwdriver).

Finally, although various advantages, aspects, and objects of the present invention have been discussed herein with reference to various embodiments, it will be understood that the scope of the invention should not be limited by reference to such advantages, aspects, and objects. Rather, the scope of the invention should be determined with reference to the appended claims.

What is claimed is:

1. A method for controlling planarity of a probe contact array in contact with a wafer contact array on a wafer comprising at least one die, the probe contact array being configured on a probe card having first kinematic reference features coupled thereto, the wafer being positioned in a wafer prober, the probe card being docked with a tester-probe card interface having second kinematic features coupled thereto, the first and second kinematic features being together operable to facilitate alignment of the probe card to the tester-probe card interface and restrain relative motion between the probe card and the wafer prober when the probe card and the tester-probe card interface are docked, the method comprising:
measuring a plurality of forces associated with at least some of the first and second kinematic reference features; and
applying a planarizing force to a back side of the probe card opposite the probe contact array to oppose deformation of the probe card, a magnitude of the planarizing force being determined with reference to the plurality of forces.

2. The method of claim 1 wherein measuring the plurality of forces comprises evaluating signals corresponding to the at least some of the first and second kinematic reference features, the signals representing the plurality of forces.

3. The method of claim 2 wherein the signals are generated using piezoelectric components integrated with each of the at least some of the first and second kinematic reference features.

4. The method of claim 2 wherein the signals are generated using a non-piezoelectric force measurement mechanism.

5. The method of claim 1 wherein applying the planarizing force to the back side of the probe card comprises adjusting a height of a stiffness support in contact with the back side of the probe card.

6. The method of claim 5 wherein adjusting the height of stiffness support comprises activating a piezoelectric component integrated with the stiffness support.

7. The method of claim 5 wherein adjusting the height of the stiffness support comprises moving the stiffness support with a mechanical mechanism.

8. The method of claim 7 wherein the mechanical mechanism is operable to be manually adjusted.
